(19) United States
(12) Patent Application Publication
(10) Pub. No.: US 2021/0074900 A1
(43) Pub. Date: Mar. 11, 2021

(54) ZrNiSn-BASED HALF-HEUSLER THERMOELECTRIC MATERIAL AND PROCESS FOR MANUFACTURING SAME AND FOR REGULATING ANTISITE DEFECTS THEREIN

(71) Applicant: Dalian University of Technology, Dalian City (CN)

(72) Inventors: Huijun KANG, Dalian City (CN); Tongmin WANG, Dalian City (CN); Xiong YANG, Dalian City (CN); Enyu GUO, Dalian City (CN); Zongning CHEN, Dalian City (CN); Tingju LI, Dalian City (CN); Zhiqiang CAO, Dalian City (CN); Yiping LU, Dalian City (CN); Jinchuan JIE, Dalian City (CN); Yubo ZHANG, Dalian City (CN)

(73) Assignee: Dalian University of Technology, Dalian City (CN)

(21) Appl. No.: 16/820,161

(22) Filed: Mar. 16, 2020

(30) Foreign Application Priority Data
Sep. 11, 2019 (CN) 201910859369.0

(51) Int. Cl. H01L 35/26; B22F 3/24; B22F 9/04; B22F 3/105; C22C 1/04; C22C 16/00; H01L 35/34

(52) U.S. Cl. CPC H01L 35/26; B22F 3/24; B22F 9/04; B22F 3/105; C22C 1/0458; B22F 2003/1051; H01L 35/34; B22F 2301/205; B22F 2009/043; B22F 2003/248; C22C 16/00

(57) ABSTRACT

The invention relates to a process for manufacturing a ZrNiSn-based half-Heusler thermoelectric material and regulating antisite defects therein, including the steps of: mixing zirconium (Zr), nickel (Ni), and stannum (Sn) at an atomic ratio of Zr: Ni: Sn=1:1:1; forming an ingot by melting the mixture in a levitation melting furnace; milling the ingot to form a milled powder followed by drying; sintering the dried powder by spark plasma sintering; and placing the sintered powder in a vacuum vessel to be subjected to heat treatment and then quenching treatment to obtain the ZrNiSn-based half-Heusler thermoelectric material. The process is simple, easy to control, and results in a single phase ZrNiSn-based half-Heusler thermoelectric material with antisite defects.

### CROSS-REFERENCE TO RELATED APPLICATIONS AND CLAIM TO PRIORITY

This application is related to Patent Application No. 201910859369.0 filed Sep. 11, 2019 in China, the disclosure of which is incorporated herein by reference and to which priority is claimed.

### FIELD OF THE INVENTION

The invention is generally related to thermoelectric materials, and in particular to a ZrNiSn-based half-Heusler thermoelectric material, and a process for manufacturing same and for regulating antisite defects therein.

### BACKGROUND OF THE INVENTION

Thermoelectric materials are of significant value in fields such as special power supply, green energy, ambient energy harvesting and industrial waste heat power generation. In recent years, many excellent thermoelectric materials with high ZT value have been found and related thermoelectric device application techniques have also been significantly developed. Thermoelectric materials are materials that can directly convert heat into electricity efficiently, have high stability and a simple structure. However, the low energy efficiency of thermoelectric materials has restricted its application. Therefore, current studies mainly focus on how to increase the thermoelectric conversion efficiency. Recently, half-Heusler alloys that have semi-conductor characteristics and demonstrated Seebeck effect show promise as a typical medium and high temperature thermoelectric material in the thermoelectric power generation field.

The performance of the thermoelectric material depends significantly on its thermoelectric figure of merit, ZT. A higher ZT value means higher thermoelectric conversion efficiency. The ZT value is given by ZT=α²σT/κ, where α is the Seebeck coefficient, σ the electrical conductivity, α²σ the power factor or PF, T the absolute temperature, κ the thermal conductivity including both the lattice (or phonon) thermal conductivity κ₁ and the electronic thermal conductivity κₑ(κ=κ₁+κₑ). Due to the fact that the Seebeck coefficient α, electrical conductivity σ, and electronic thermal conductivity κₑ are sensitively interdependent via carrier concentration n, when high electrical conductivity σ is obtained by turning n, this tends to result in a low Seebeck coefficient α and high electronic thermal conductivity κₑ. Ways to effectively increase the ZT value is a continuing problem in the art.

Half-Heusler compounds are thought to be a potential thermoelectric material that can be mass produced commercially and have good application prospects because of their chemical stability, high-temperature thermal stability, excellent mechanical properties, and high ZT value. However, the thermoelectric performance of ZrNiSn-based half-Heusler compounds is sensitive to the manufacturing processes, and different manufacturing processes cause changes of microstructures and atomic disorder of the compound material. These defects can easily be formed in-situ in the high temperature manufacturing process because zirconium and stannum have a similar atomic radius, which is then recovered by annealing. When the content of Zr/Sn anti site defects increases to a certain level, the ZrNiSn-based thermoelectric material with semi-conductor characteristics can be converted into those having semi-metallic characteristics. However, the previous methods make it very difficult to obtain a single-phase material and control the defects.

### SUMMARY OF THE INVENTION

In view of the above mentioned problem, that is, the ZT value of the current thermoelectric materials cannot be improved effectively, the invention aims to provide a process for manufacturing a ZrNiSn-based half-Heusler thermoelectric material and regulating antisite defects within the ZrNiSn matrix, which is simple and easy to control. The method enables manufacture of a single-phase ZrNiSn-based half-Heusler thermoelectric material wherein it is easy to control the antisite defects therein.

Accordingly, an object of the invention is realized by a process for manufacturing a ZrNiSn-based half-Heusler thermoelectric material and regulating antisite defects therein, comprising the steps of mixing zirconium (Zr), nickel (Ni), and stannum (Sn) at an atomic ratio of Zr:Ni:Sn=1:1:1 in an argon atmosphere or in a sealed and oxygen free environment; forming an ingot by melting the mixture in a levitation melting furnace; milling the ingot to form a milled powder followed by drying; sintering the dried powder by spark plasma sintering; and placing the sintered powder in a vacuum vessel to be subjected to heat treatment and then a quenching treatment to obtain a ZrNiSn-based half-Heusler thermoelectric material.

More specifically, the process for manufacturing a ZrNiSn-based half-Heusler thermoelectric material and regulating antisite defects therein may comprise steps of:

(1) mixing Zr, Ni, and Sn at an atomic ratio of Zr:Ni:Sn=1:1:1 in argon atmosphere or in a sealed and oxygen free environment to prevent oxidation;

(2) forming an ingot by melting the mixture in argon atmosphere in a levitation melting furnace, with the mixture heated to a temperature of 1600 to 1800° C., preferably 1650 to 1750° C. and maintaining that temperature for 1 to 5 mins, preferably 3 to 5 mins;

(3) ball-milling the ingot to form a ball-milled powder having a particle size of about 0.5 to 2 μm followed by natural drying;

(4) sintering the dried powder by spark plasma sintering at 800 to 1000° C., preferably 900 to 1000° C. under 80 to 100 MPa, preferably 80 to 100 MPa for about 5 to 20 mins, preferably about 10 to 20 mins;

(5) placing the sintered powder into a vacuum vessel;

(6) placing the vacuum vessel containing the powder into a box-type high-temperature sintering furnace and subjecting the powder to a long-duration diffusion annealing process with an annealing temperature of 800 to 1100° C., preferably 900 to 1000° C. and an incubation time of 12 to 36 h, preferably 24 to 36 h; and

(7) subjecting the incubated powder contained in the vacuum vessel to a rapid quenching treatment with a temperature descending rate of 200 to 300° C./min, to obtain a ZrNiSn-based half-Heusler thermoelectric material.

Further, each of Zr, Ni, and Sn may have a purity of greater than or equal to about 99.9%.

Further, each of Zr, Ni, and Sn may be implemented as particles with a diameter of about 1 to 2 mm and a length of about 2 to 5 mm.

Further, the melting step (2) may be carried out 3 to 6 times to ensure uniformity of the structure after the melting step.

Further, the argon atmosphere may be applied at a pressure of 10⁴ to 10⁵ Pa.

Further, in milling step (3), the ingot may be initially ground into a powder with a particle size of about 0.1 to 1 mm by using a mortar and then be subjected to wet-ball-milling in an argon atmosphere. Anhydrous ethanol may be used as a ball-milling medium. The ball-to-powder ratio may be within a range of 10:1 to 20:1. The rotation speed may be within a range of 200 to 600 r/min. The milling time may be within a range of about 5 to 20 h.

Further, in the milling step (3), the ball-milled powder may be subjected to suction filtration and may be allowed to dry naturally for 12 to 48 h in an argon atmosphere or in a sealed and oxygen free environment.

Further, in step (5), the vacuum pressure of the vacuum vessel may be less than or equal to about 5×10⁻³ Pa. The vacuum vessel may include, but is not limited to, a quartz glass tube having a diameter of 15 to 30 mm.

Further, in quenching step (7), water may be used as a quenching medium for the quenching treatment.

A further object of the invention is to provide a ZrNiSn-based half-Heusler thermoelectric material manufactured by the process mentioned above.

Compared with the prior art, the process for manufacturing a ZrNiSn-based half-Heusler thermoelectric material and regulating antisite defects therein according to the invention has several advantages.

Aiming at the ZrNiSn alloy and employing levitation melting and spark plasma sintering, a single-phase ZrNiSn-based thermoelectric material is manufactured, and antisite defect content is regulated by using different heat treatment processes. X-ray diffraction (XRD) may be utilized to characterize composition of samples, and the thermoelectric properties may be tested. Results shows that the ZrNiSn-based half-Heusler thermoelectric materials having antisite defects manufactured by the process of the invention, are simple to manufacture with a process that is easy to control. Regulation of antisite defects enables related thermoelectric performance parameters to be effectively adjusted. Thus, the thermoelectric figure of merit, ZT, can be improved. The above results demonstrate that the ZrNiSn-based half-Heusler thermoelectric material can be effectively manufactured by levitation melting in combination with spark plasma sintering, and the content of the antisite defects can be effectively regulated by different heat treatment processes.

XRD patterns of the sintered samples show that all the ZrNiSn-based samples with different heat treatment processes are indexed as a single phase. Electrical conductivity of the material may be measured with a four-probe method by using a laser flash thermal analyzer. Results show that each of the antisite defects and the electrical conductivity of the samples decreases gradually with the increase of the annealing temperature. Through calculations, it was found that the power factor of the samples decreases with the decrease of the antisite defects. Final calculation results demonstrate that the increase of the antisite defects enables effective increase of the thermoelectric figure of merit ZT. The invention provides a process that is able to manufacture a single phase ZrNiSn-based half-Heusler thermoelectric material with antisite defects, and discloses the effect of the antisite defects on the thermoelectric performance of the material.

### BRIEF DESCRIPTION OF THE DRAWINGS

FIG. 1 shows XRD patterns of different samples sintered by spark plasma sintering;

FIG. 2 shows electrical conductivity of samples of a ZrNiSn-based half-Heusler thermoelectric material subjected to different heat treatment processes;

FIG. 3 shows power factor of samples of ZrNiSn-based half-Heusler thermoelectric material subjected to different heat treatment processes; and

FIG. 4 shows thermoelectric figure of merit of samples of ZrNiSn-based half-Heusler thermoelectric material subjected to different heat treatment processes.

### DETAILED DESCRIPTION OF THE PREFERRED EMBODIMENT(S)

The invention will be further described in detail below with reference to examples.

### Example 1

A single phase ZrNiSn-based half-Heusler thermoelectric material having antisite defects was manufactured. Zr, Ni, and Sn were mixed at an atomic ratio of Zr:Ni:Sn=1:1:1. The mixture having 33.3% Zr, 33.3% Ni, and 33.3% Sn was then melted.

Further, the ZrNiSn-based half-Heusler thermoelectric material with antisite defects, ball-milled, had a grain size of 0.5 to 2 μm.

In particular, the material was manufactured according to the following steps:

(1) preparing raw material: preparing Zr, Ni, and Sn particles with a diameter of about 2 mm and a length of about 5 mm and a purity of greater than or equal to 99.9% as raw material;

(2) oxidation prevention: mixing the Zr, Ni, and Sn particles at a nominal atomic ratio of Zr:Ni: Sn=1:1:1 in a glove box;

(3) melting: melting the mixture in an argon atmosphere (applied at a pressure of 10⁴ to 10⁵ Pa) in a levitation melting furnace to form an ingot, heating the mixture up to 1600 to 1800° C. and then maintaining that temperature for about 3 min, and re-melting the ingot about four times to ensure component homogeneity in the levitation melting furnace;

(4) ball-milling: initially grinding the ingot into a powder with a particle size of about 0.1 to 1 mm and then subjecting the ground powder to wet-ball-milling in argon atmosphere, with anhydrous ethanol as a ball-milling medium, a ball-to-powder ratio of 15 to 1, a rotation speed of 500 r/min, and a milling time of 10 h;

(5) drying: allowing the milled powder subjected to suction filtration to dry naturally for 24 h in a glove box;

(6) sintering: sintering the dried powder by spark plasma sintering at 1000° C. under 100 MPa for 15 min;

(7) sealing: placing the sintered powder at a treatment temperature of 900° C. into a quartz glass tube with a diameter of 20 mm, and vacuuming and sealing the tube such that the tube had a degree of vacuum of less than or equal to 5×10⁻³ Pa;

(8) heat treating: subjecting the sample sealed in the vacuum tube to a long-duration diffusion annealing treatment in a box-type high-temperature sintering furnace, with an annealing temperature of 900° C. and an incubation time of 24 h; and

(9) quenching: subjecting the incubated sample to a rapid quenching treatment with water as a quenching medium, to form the ZrNiSn-based half-Heusler thermoelectric material having a grain size of about 0.5 to 2 μm.

### Example 2

(1) preparing raw material: preparing Zr, Ni, and Sn particles with a diameter of 2 mm and a length of 5 mm and a purity of greater than or equal to 99.9% as raw material;

(2) oxidation prevention: mixing the Zr, Ni, and Sn particles at a nominal atomic ratio of Zr:Ni: Sn=1:1:1 in a glove box;

(3) melting: melting the mixture in an argon atmosphere (applied at a pressure of 10⁴ to 10⁵ Pa) in a levitation melting furnace to form an ingot, with the mixture to be heated up to 1600 to 1800° C., maintaining that temperature for 4 min, and re-melting the ingot three times to ensure component homogeneity in the levitation melting furnace;

(4) ball-milling: initially grinding the ingot into a powder with a particle size of about 0.1 to 1 mm and then subjecting the ground powder to wet-ball-milling in an argon atmosphere, with anhydrous ethanol as a ball-milling medium and a ball-to-powder ratio of 20 to 1, a rotation speed of 600 r/min, and a milling time of 8 h;

(5) drying: allowing the milled powder subjected to suction filtration to dry naturally for 20 h in a glove box;

(6) sintering: sintering the dried powder by spark plasma sintering at 950° C. under 90 MPa for 20 mins;

(7) sealing: placing the sintered powder sample at a temperature of 950° C. into a quartz glass tube with a diameter of 20 mm, and vacuuming and sealing the tube such that the tube had a degree of vacuum of less than or equal to 5×10⁻³ Pa;

(8) heat treating: subjecting the sample sealed in the tube to a long-duration diffusion annealing treatment in a box-type high-temperature sintering furnace, with an annealing temperature of 950° C. and an incubation time of 20 h.

(9) quenching: subjecting the incubated sample to a rapid quenching treatment with water as a quenching medium, to form the ZrNiSn-based half-Heusler thermoelectric material having a grain size of about 0.5 to 2 μm.

Test Results

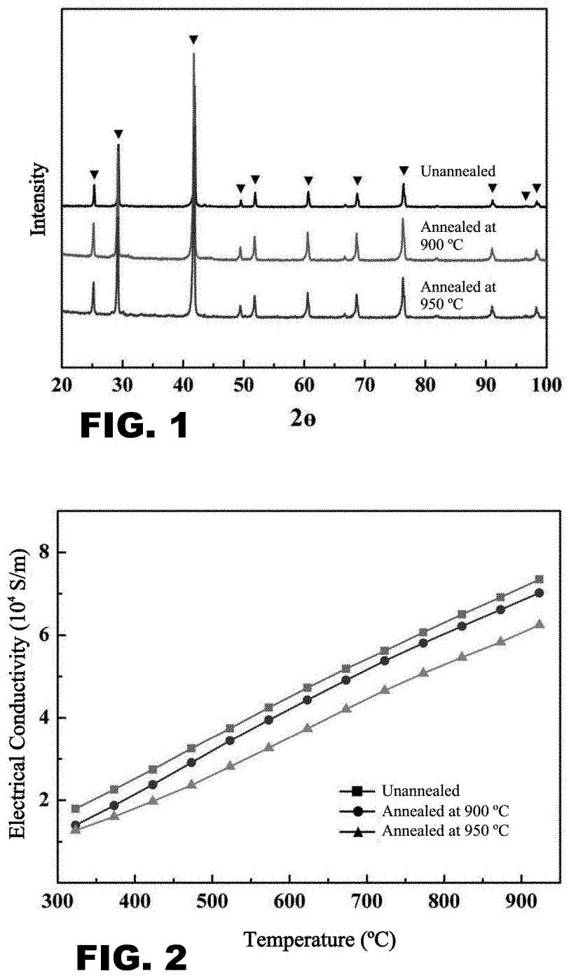

FIG. 1 shows XRD patterns of the as-sintered samples with different heat treatment processes. It can be seen that the samples of the ZrNiSn-based thermoelectric material with different heat treatment processes were of single phase.

FIG. 2 shows electrical conductivity of the samples of the ZrNiSn-based half-Heusler thermoelectric material with different heat treatment processes. It can be seen that the electrical conductivity of the samples decreased gradually with the increase of the annealing temperature, showing that the electrical conductivity decreased from 7.35×10⁴ S/m to 6.25×10⁴ S/m at 923 K.

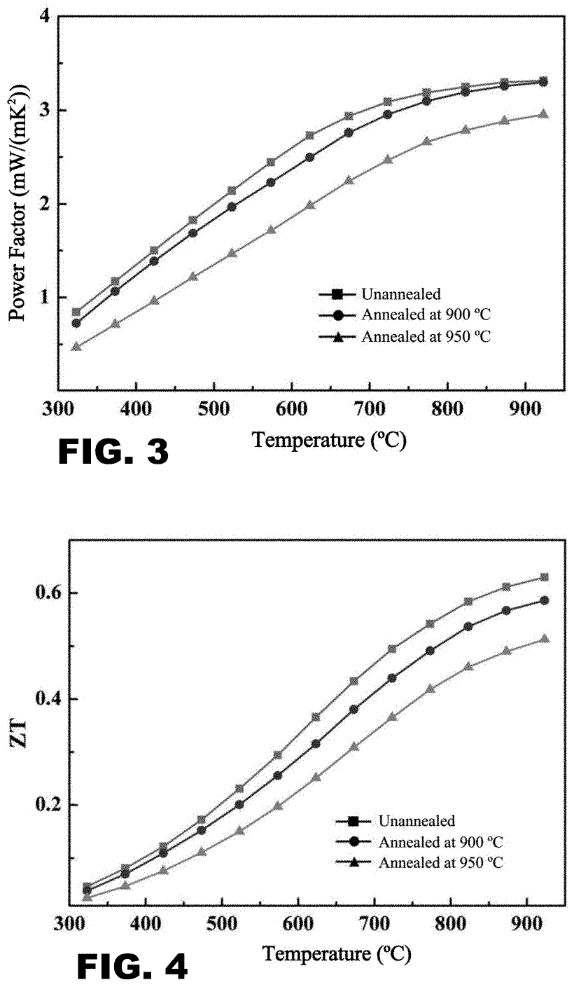

FIG. 3 shows the power factor of the samples of the ZrNiSn-based half-Heusler thermoelectric material with different heat treatment processes. It can be seen that the power factor of the samples gradually decreased with the increase of the annealing temperature, showing that the power factor decreased from 3.31 to 2.95 at 923 K.

FIG. 4 shows thermoelectric figure of merit of the samples of the ZrNiSn-based half-Heusler thermoelectric material with different heat treatment processes. It can be seen that, the thermoelectric figure of merit, ZT, decreased gradually with the increase of the annealing temperature, showing that the ZT decreased from 0.63 to 0.51 at 923 K.

In the examples, single phase ZrNiSn-based thermoelectric material with different content of antisite defects were manufactured, and the content of antisite defect was regulated by using different heat treatment processes. The XRD results showed that all the samples manufactured were of single phase. Results also showed that the increase of the annealing temperature resulted in a higher driving force for the recovery of the antisite defects, and thus a sample under a higher annealing temperature had fewer antisite defects after the rapid quenching step. The thermoelectric performance results showed that the electrical conductivity and power factor increased gradually with the increase of the antisite defect density, and thus the thermoelectric figure of merit, ZT, was improved. The single phase ZrNiSn-based half-Heusler thermoelectric material having antisite defects was manufactured, and was qualitatively and quantitatively analyzed. The effect of the antisite defects on the thermoelectric performance of the ZrNiSn-based Half-Heusler thermoelectric material was also disclosed.

It should be noted that the examples above are for the purpose of illustration and not to limit the scope of the invention. Although the invention herein has been described with reference to particular embodiments by way of examples, it should be understood by those skilled in the art, that various modifications or equivalents may be made without departing from the spirit or scope of the invention.

What is claimed is:

1. A process for manufacturing a ZrNiSn-based half-Heusler thermoelectric material and regulating antisite defects therein, comprising steps of:
mixing zirconium (Zr), nickel (Ni), and stannum (Sn) at an atomic ratio of Zr:Ni:Sn=1:1:1;
forming an ingot by melting the mixture in a levitation melting furnace;
milling the ingot to form a milled powder followed by drying;
sintering the dried powder by spark plasma sintering; and
placing the sintered powder in a vacuum vessel to be subjected to heat treatment and then quenching treatment to obtain the ZrNiSn-based half-Heusler thermoelectric material.

2. The process according to claim 1, comprising steps of:
(1) mixing Zr, Ni, and Sn at an atomic ratio of Zr: Ni: Sn=1:1:1;
(2) forming an ingot by melting the mixture in an argon atmosphere in a levitation melting furnace, with the mixture heated to a temperature of 1600 to 1800° C. and maintained at that temperature for 1 to 5 min;
(3) ball-milling the ingot to form a ball-milled powder having a particle size of 0.5 to 2 μm followed by natural drying;
(4) sintering the dried powder by spark plasma sintering at 900 to 1100° C. under 80 to 100 MPa for 5 to 20 min;
(5) placing the sintered powder into a vacuum vessel;
(6) placing the vacuum vessel containing the powder into a box-type high-temperature sintering furnace and subjecting the powder to a long-duration diffusion annealing process with an annealing temperature of 800 to 1100° C. and an incubation time of 12 to 36 h; and
(7) subjecting the incubated powder to a rapid quenching treatment to form the ZrNiSn-based half-Heusler thermoelectric material.

3. The process according to claim 1, wherein, each of Zr, Ni, and Sn has a purity of greater than or equal to 99.9%.

4. The process according to claim 2, wherein, each of Zr, Ni, and Sn has a purity of greater than or equal to 99.9%.

5. The process according to claim 2, wherein, the melting step (2) is carried out 3 to 6 times.

6. The process according to claim 2, wherein, the argon atmosphere is applied at a pressure of 10⁴ to 10⁵ Pa.

7. The process according to claim 2, wherein, in step (3), the ingot is initially ground into a powder with a particle size of 0.1 to 1 mm by using a mortar and then subjected to wet-ball-milling in argon atmosphere, wherein, anhydrous ethanol is used as a ball-milling medium, a ball-to-powder ratio is within a range of 10:1 to 20:1, a rotation speed is within a range of 200 to 600 r/min and a milling time is within a range of 5 to 20 h.

8. The process according to claim 2, wherein, in step (3), the ball-milled powder subjected to suction filtration is allowed to dry naturally for 12 to 48 h in argon atmosphere or a sealed and oxygen free environment.

9. The process according to claim 2, wherein, in step (5), a vacuum level of the vacuum vessel is less than or equal to 5×10⁻³ Pa.

10. The process according to claim 2, wherein, in step (7), water is used as a quenching medium for the quenching treatment.

11. A ZrNiSn-based half-Heusler thermoelectric material manufactured by the process according to claim 1.

12. A ZrNiSn-based half-Heusler thermoelectric material manufactured by the process according to claim 2.

13. A ZrNiSn-based half-Heusler thermoelectric material manufactured by the process according to claim 3.

14. A ZrNiSn-based half-Heusler thermoelectric material manufactured by the process according to claim 4.

15. A ZrNiSn-based half-Heusler thermoelectric material manufactured by the process according to claim 5.

16. A ZrNiSn-based half-Heusler thermoelectric material manufactured by the process according to claim 6.

17. A ZrNiSn-based half-Heusler thermoelectric material manufactured by the process according to claim 7.

18. A ZrNiSn-based half-Heusler thermoelectric material manufactured by the process according to claim 8.

19. A ZrNiSn-based half-Heusler thermoelectric material manufactured by the process according to claim 9.

20. A ZrNiSn-based half-Heusler thermoelectric material manufactured by the process according to claim 10.
